(19) United States
(12) Patent Application Publication
(10) Pub. No.: US 2026/0126495 A1
(43) Pub. Date: May 7, 2026

(54) DEVICE AND METHOD FOR DETECTING BATTERY ABNORMAL CONDITION USING VOLTAGE DEVIATION VARIATION

(71) Applicant: SK ON CO., LTD., Seoul (KR)

(72) Inventors: Kyu Min HWANG, Daejeon (KR); Hyun Jun LEE, Daejeon (KR); Ung JON, Daejeon (KR); Myeong Jae GO, Daejeon (KR)

(21) Appl. No.: 19/378,338

(22) Filed: Nov. 4, 2025

(30) Foreign Application Priority Data
Nov. 4, 2024 (KR) 10-2024-0154386

(51) Int. Cl. G01R 31/3835; B60L 58/12; B60L 58/16; G01R 31/367; G01R 31/392; G01R 31/396; H01M 10/42

(52) U.S. Cl. CPC G01R 31/3835; G01R 31/367; G01R 31/392; G01R 31/396; H01M 10/4285; B60L 58/12; B60L 58/16

(57) ABSTRACT

The present disclosure relates to a device and a method for detecting a battery abnormality using a voltage deviation variation. According to one embodiment of the present disclosure, the device includes: a memory configured to store at least one instruction for detecting a battery abnormality using a voltage deviation variation; and a processor configured to perform an operation according to the instruction, wherein the processor is configured to: calculate a voltage change of the battery and store the calculated voltage change as a variable; and calculate a Differential Deviation Voltage Detection (DDVD), which is a change in voltage difference among respective cells within a battery module, and detect a battery abnormality using the voltage deviation variation (DDVD) and the stored variable.

### CROSS-REFERENCE TO RELATED APPLICATIONS

This application claims priority under 35 U.S.C. § 119 to Korean Patent Application No. 10-2024-0154386, filed on Nov. 4, 2024, the disclosure of which is incorporated herein by reference in its entirety.

### BACKGROUND OF THE INVENTION

### 1. Field of the Invention

The present disclosure relates to a device and a method for detecting a battery abnormality using a voltage deviation variation.

### 2. Description of the Related Art

To ensure the safety and performance of batteries used in various industries and electronic devices, battery abnormality detection technologies are essential. A battery is a device that stores and releases energy through internal chemical reactions. If excessive heat is generated during the energy storage and release processes, there are risks such as fire or explosion. Therefore, battery abnormality detection technologies may detect such risks in advance and prevent accidents.

Lithium-ion batteries are efficient due to their high energy density, but when overcharging overdischarging, or short-circuiting occurs, serious safety issues may arise. Battery abnormality detection technologies can identify these issues at an early stage, thereby protecting users and the surrounding environment. In addition, battery abnormality detection technologies may analyze the state of the battery, detect early signs of failure, and enable preventive maintenance when necessary. This may prevent abnormal battery operation and extend its life cycle.

Meanwhile, conventional battery abnormality detection methods primarily detect voltage changes by setting a fixed threshold value. In such conventional detection methods, if a voltage change exceeds the fixed threshold value, it is determined that the battery is abnormal. However, because it is difficult to appropriately set the threshold value for all operating conditions, it is challenging to accurately diagnose the battery state and detect abnormalities. Specifically, voltage changes may vary greatly depending on factors such as the battery state, usage environment, and temperature. Since the fixed threshold value in conventional detection methods fails to adequately reflect these diverse factors, accurate diagnosis and abnormality detection are difficult.

Further, when a battery experiences large current changes, even a normal cell may exceed a fixed threshold value. For example, during fast charging or high-power discharging, even a healthy battery may exhibit a large voltage change. However, relying solely on a fixed threshold value in such cases increases the likelihood of misdiagnosing a normal battery as defective.

Furthermore, conventional battery abnormality detection methods cannot distinguish between voltage changes naturally caused by battery aging and those caused by actual abnormalities, which makes accurate diagnosis of the battery state difficult. An aged battery may exhibit a different voltage change pattern, but it is difficult to distinguish voltage and current changes caused by aging using only the fixed threshold value.

### SUMMARY OF THE INVENTION

According to one aspect of the present disclosure, there are provided a device and a method for detecting signs of battery abnormality before a fire occurs, by setting a variable threshold value based on a current change using a relational equation of a battery equivalent model, and detecting the battery abnormality based on the set variable threshold value.

According to another aspect of the present disclosure, in cases where parameters used in the relational equation of the battery equivalent model vary depending on battery degradation or ambient temperature, errors may occur in the calculated threshold value. In this regard, in some embodiments, by monitoring changes in cell deviation within a battery module instead of relying on the relational equation of a single cell, the effect of parameter errors may be reduced using relative values.

A device for detecting a battery abnormality using a voltage deviation variation according to one embodiment of the present disclosure may include: a memory configured to store at least one instruction for detecting a battery abnormality using a voltage deviation variation; and a processor configured to perform an operation according to the instruction, wherein the processor may be configured to: calculate a voltage change of the battery and store the calculated voltage change as a variable; and calculate a Differential Deviation Voltage Detection (DDVD), which is a change in voltage difference among respective cells within a battery module, and detect a battery abnormality using the Differential Deviation Voltage Detection (DDVD) and the stored variable.

According to one embodiment, the processor may include a battery equivalent-model voltage change calculation unit configured to calculate a voltage change of the battery using parameters related to a State of Charge (SOC) of the battery when a current is applied to an Equivalent Circuit Model (ECM).

According to one embodiment, the processor may include a driving-distance reflection unit configured to, when an accumulated driving distance exceeds a predetermined value, adjust a ratio of at least one of the calculated values of the voltage change in the battery equivalent model by taking into account degradation differences among cells within the battery module, and set the adjusted calculated value as a voltage deviation variation (DDVD) criterion.

According to one embodiment, the parameters related to the State of Charge (SOC) may include a voltage change (Δt/C₁ (Iₖ−Iₖ₋₁) due to capacitance of the battery equivalent model and circuit characteristics (1−Δt/R₁C₁) of an RC circuit.

According to one embodiment, the driving-distance reflection unit may be configured to compare the calculated voltage deviation variation criterion with driving results of a normal battery, and adjust an increase or decrease of the criterion according to a current level.

A method for detecting a battery abnormality using a voltage deviation variation according to one embodiment of the present disclosure may include: calculating a voltage change of the battery and storing the calculated voltage change as a variable; and calculating a Differential Deviation Voltage Detection (DDVD), which is a change in voltage difference among respective cells within a battery module, and detecting a battery abnormality using the Differential Deviation Voltage Detection (DDVD) and the stored variable.

According to one embodiment, the step of detecting a battery abnormality may include: calculating, by a battery equivalent-model voltage change calculation unit, a voltage change of the battery using parameters related to a State of Charge (SOC) of the battery when a current is applied to an Equivalent Circuit Model (ECM).

According to one embodiment, the step of calculating a voltage change of the battery may include: when an accumulated driving distance exceeds a predetermined value, by a driving-distance reflection unit, adjusting a ratio of at least one of the calculated values of the voltage change in the battery equivalent model by taking into account degradation differences among cells within the battery module, and setting the adjusted calculated value as a voltage deviation variation (DDVD) criterion.

According to one embodiment, the parameters related to the State of Charge (SOC) may include a voltage change (Δt/C₁ (Iₖ−Iₖ₋₁)) due to capacitance of the battery equivalent model and circuit characteristics (1−Δt/R₁C₁) of an RC circuit.

According to one embodiment, the step of setting the adjusted calculated value as a voltage deviation variation (DDVD) criterion may include: comparing the calculated voltage deviation variation criterion with driving results of a normal battery: and adjusting an increase or decrease of the criterion according to a current level.

According to one embodiment, various embodiments of the present disclosure provide an effect of enabling adaptation to various operating conditions and changes in the battery state by dynamically adjusting a threshold value for determining battery abnormality based on a current change.

According to one embodiment, various embodiments of the present disclosure may reduce battery abnormality detection errors by setting a voltage change, which serves as a criterion for abnormality determination, as a variable using a battery equivalent model instead of as a constant, thereby reflecting current usage patterns.

According to one embodiment, various embodiments of the present disclosure may manage the battery based on a voltage deviation variation instead of a voltage change, thereby further reducing abnormality detection errors caused by errors in parameters used in the battery equivalent model.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a diagram illustrating a device for detecting a battery abnormality using a voltage deviation variation (“battery abnormality detection device”) according to one embodiment of the present disclosure;

FIG. 2 is a block diagram illustrating the battery abnormality detection device using a voltage deviation variation according to one embodiment of the present disclosure;

FIG. 3 is a diagram illustrating the configuration of a processor according to one embodiment of the present disclosure;

FIG. 4 is a graph showing test results analyzing the voltage deviation of a battery using the Differential Deviation Voltage Detection (DDVD) criterion according to one embodiment of the present disclosure;

FIG. 5 is a graph illustrating the voltage deviation variation criterion and the deviation change of a monitored Equivalent Circuit Model (ECM) according to one embodiment of the present disclosure; and

FIG. 6 is a flowchart illustrating a method for detecting a battery abnormality using a voltage deviation variation (“battery abnormality”).

### DETAILED DESCRIPTION OF THE INVENTION

Hereinafter, exemplary embodiments of the present disclosure will be described in detail with reference to the accompanying drawings. However, these embodiments are merely illustrative, and the present disclosure is not limited to the specific embodiments described as examples.

Although “first,” “second,” and the like may be used to describe various elements, components, and/or sections, these elements, components, and/or sections are not limited by these terms. These terms are merely used to distinguish one element, component, and/or section from another. Therefore, it will be understood that the first element, first component, or first section mentioned below may also be a second element, second component, or second section within the technical spirit of the present invention.

The terminology used herein is for the purpose of describing particular embodiments only and is not intended to limit the present invention. As used herein, the singular forms are intended to include the plural forms as well, unless the context clearly indicates otherwise. It will be further understood that the terms “comprises” and/or “made of,” as used herein, do not preclude the presence or addition of one or more other components, steps, operations, and/or elements in addition to the explicitly recited component, step, operation, and/or element.

Unless otherwise defined, all terms (including technical and scientific terms) used herein have the same meaning as commonly understood by those skilled in the art to which the present invention pertains. Terms defined in commonly used dictionaries are not to be construed in an idealized or overly formal sense unless expressly defined herein.

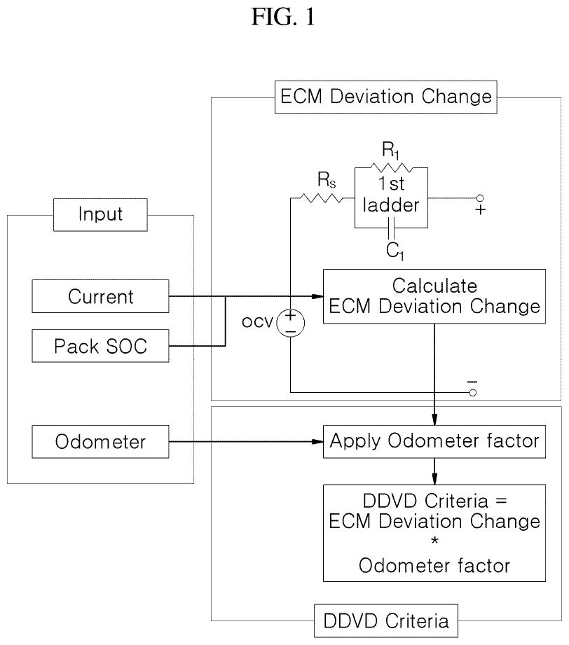

FIG. 1 is a diagram illustrating a battery abnormality detection device using a voltage deviation variation according to one embodiment of the present disclosure.

Referring to FIG. 1, the battery abnormality detection device according to one embodiment of the present disclosure detects signs of a battery abnormality based on Differential Deviation Voltage Detection (DDVD, hereinafter also referred to as voltage deviation variation (DDVD), or simply DDVD). DDVD is a criterion that monitors the state of battery cells and detects abnormalities in a battery management system (BMS). The DDVD criterion analyzes the voltage changes of battery cells to enable early detection of abnormal states or signs of failure. For example, the voltage of a battery cell changes during the charging and discharging processes and should remain within a normal range. The battery abnormality detection device according to one embodiment enables detection of voltage changes that deviate from the normal range or change abnormally using the DDVD, thereby determining whether the battery is abnormal. In addition, the device of the present disclosure monitors voltage changes in real time using the DDVD, which is a voltage deviation variation, thereby detecting abnormalities even under rapidly changing conditions. Further, the battery abnormality detection device according to one embodiment of the present disclosure may determine whether an abnormality exists based on the voltage deviation between a specific cell and surrounding cells. If the voltage of the specific cell shows a significant difference compared to other cells, the device of the present disclosure may determine that the cell exhibits signs of cell degradation or failure. Furthermore, if the voltage change exceeds a predetermined threshold value, the battery abnormality detection device according to one embodiment of the present disclosure may determine that the corresponding cell is abnormal and issue a warning based on the DDVD criterion.

As shown in FIG. 1, the battery abnormality detection device according to one embodiment of the present disclosure calculates a voltage deviation variation (DDVD) criterion using a current, State of Charge (SOC)-related data (Pack SOC), and a driving distance acquired through an odometer. In the present disclosure, the current refers to the current flowing through a battery module, which is a key parameter that significantly affects the voltage and internal state of the battery. The SOC-related data (Pack SOC) represent parameters indicating the state of the battery, including at least one of the State of Charge (SOC), voltage change due to capacitance, and RC circuit characteristics. The driving distance is collected through an odometer, which is a device configured to measure the driving distance of the battery module. In the case of an electric vehicle, the odometer is used to monitor battery degradation and performance changes according to the driving distance.

In the present disclosure, the battery abnormality detection device calculates an ECM voltage deviation variation using a current and SOC-related parameters. The ECM voltage deviation variation is calculated based on the current and SOC input data using an Equivalent Circuit Model (ECM) to determine the voltage change and deviation of the battery. The ECM represents the electrical behavior of the battery through circuit components such as resistors and capacitors, thereby indicating changes in the battery state. Thereafter, the battery abnormality detection device applies a ratio factor according to the driving distance; for example, it reflects the influence of the driving distance on the ECM voltage deviation variation by using a ratio corresponding to the driving distance obtained from an odometer. This enables more accurate abnormality detection by considering battery degradation and performance changes that may occur as the driving distance increases. Subsequently, the battery abnormality detection device calculates a voltage deviation variation (DDVD) criterion, which may be determined according to Equation 1.

$$Voltage Deviation Variation ( DDVD ) Criterion = ECM Voltage Deviation Variation \times Odometer Factor \qquad [ Equation 1 ]$$

According to one embodiment, the battery abnormality detection device finally calculates a voltage deviation variation (DDVD) criterion by multiplying an ECM voltage deviation variation by an odometer factor. The calculated voltage deviation variation criterion is used to dynamically detect voltage deviations among battery cells, thereby enabling early detection of cell imbalance or abnormal states.

The battery abnormality detection device using a voltage deviation variation according to one embodiment of the present disclosure utilizes various input data during the process of setting a voltage deviation variation (DDVD) criterion to accurately assess the state of the battery and enable early detection of abnormalities. Through this approach, the safety, efficiency, and life cycle of the battery can be optimized, and the reliability of battery modules in electric vehicles and large-scale energy storage systems can be significantly enhanced.

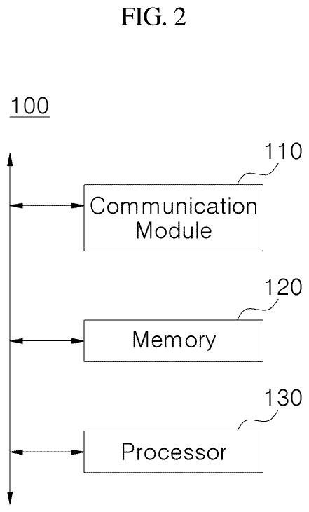

FIG. 2 is a block diagram illustrating the battery abnormality detection device using a voltage deviation variation according to one embodiment of the present disclosure.

As shown in FIG. 2, the battery abnormality detection device of the present disclosure may include a communication module 110, a memory 120, and a processor 130. The configuration of the battery abnormality detection device using a voltage deviation variation shown in FIG. 2 is merely a simplified example. The communication module 110 may be configured in any communication mode, such as wired or wireless, and may be implemented through various communication networks such as a Personal Area Network (PAN) or a Wide Area Network (WAN). In addition, the communication module 110 may operate based on the World Wide Web (WWW) and may also utilize wireless transmission technologies for short-range communication, such as Infrared Data Association (IrDA) or Bluetooth. For example, the communication module 110 may perform transmission and reception of data required to execute a technique according to one embodiment of the present disclosure.

The memory 120 may refer to any type of storage medium. For example, the memory 120 may include at least one type of storage medium selected from a flash memory type, a hard disk type, a multimedia card micro type, a card-type memory (e.g., an SD or XD memory), Random Access Memory (RAM), Static Random Access Memory (SRAM), Read-Only Memory (ROM), Electrically Erasable Programmable Read-Only Memory (EEPROM), Programmable Read-Only Memory (PROM), a magnetic memory, a magnetic disk, or an optical disk. The memory 120 may also form or constitute a database configured to store various data necessary for the operation of the battery abnormality detection device 100.

The memory 120 may store at least one instruction executable by the processor 130. In addition, the memory 120 may store any type of information generated or determined by the processor 130 and any type of information received from a server (not shown). For example, the memory 120 may store user-specific RM data and RM protocols, as described below. Furthermore, the memory 120 may store various types of modules, instruction sets, and models.

The processor 130 may perform the technical features of the present disclosure according to embodiments described below by executing at least one instruction stored in the memory 120. In one embodiment, the processor 130 may be configured to include at least one core and may include a processor for data analysis and/or processing, such as a Central Processing Unit (CPU), a General Purpose Graphics Processing Unit (GPGPU), or a Tensor Processing Unit (TPU).

The processor 130 may train a neural network or a model designed using machine learning or deep learning techniques. To this end, the processor 130 may perform computations for training a neural network, including processing input data for training, extracting features from the input data, calculating errors, and updating neural network weights through backpropagation. In addition, the processor 130 may perform inference for a predetermined purpose using a model implemented based on techniques such as an artificial neural network.

In one embodiment, the processor 130 may calculate a voltage change of a battery and store the calculated voltage change as a variable. To this end, the voltage may be measured using a sensor or an Analog-to-Digital Converter (ADC), and the processor 130 may periodically read the measured voltage. The voltage change may be calculated as a difference between a currently measured voltage and a previously measured voltage. For this purpose, the embodiment may store the previous voltage value and update the stored value when a new measurement is obtained. In one embodiment, the variable for storing the measured voltage change may be stored in a memory, a file, a database, or the like.

Further, the processor 130 may calculate a voltage deviation variation (DDVD), which represents a change in voltage difference between cells within a battery module, and may detect a battery abnormality using the calculated voltage deviation variation (DDVD) and the stored variable.

Hereinafter, a method for measuring a voltage deviation variation (DDVD) among respective cells within a battery module and detecting a battery abnormality based on the measurement will be described. A battery pack includes multiple cells connected in series or in parallel, and each cell may have a different voltage due to its chemical properties or external factors. This voltage difference may change over time, and monitoring such changes is important for ensuring the safety and performance of the battery. In one embodiment, the processor 130 may periodically measure the voltage of each battery cell. The measurement may be performed using a sensor such as an Analog-to-Digital Converter (ADC). The processor 130 may then collect and store voltage data of all cells in real time and calculate voltage differences between adjacent cells. For example, the processor 130 may calculate the voltage difference between Cell 1 and Cell 2, between Cell 2 and Cell 3, and so on. In addition, the voltage deviation variation (DDVD) may be calculated by comparing the previously measured voltage difference with the currently measured voltage difference.

The range of voltage deviation variation expected under normal states may be set. The setting may be based on experimental data or information provided by the manufacturer. In addition, the threshold value may be adjusted in consideration of various factors such as temperature, load conditions, and the battery's life cycle. Furthermore, in one embodiment, if the voltage deviation variation exceeds the set threshold value, the device may determine that the cell is in an abnormal state. This may indicate a potential issue such as cell imbalance, cell damage, or overcharge and/or overdischarge. In one embodiment, when an abnormal state is detected, the system may issue a warning to the user and, if necessary, suspend battery charging and discharging or switch to a safe mode.

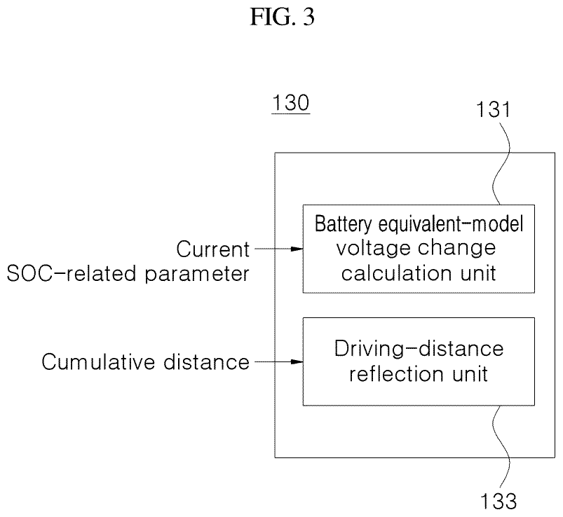

FIG. 3 is a diagram illustrating the configuration of the processor 130 according to one embodiment of the present disclosure.

Referring to FIG. 3, the processor 130 according to one embodiment may be configured to include a battery equivalent-model voltage change calculation unit 131 and a driving-distance reflection unit 133. The term “unit” used herein should be interpreted to include software, hardware, or a combination thereof, depending on the context in which the term is used. For example, software may include machine language, firmware, embedded code, or application software. As another example, hardware may include a circuit, a processor, a computer, an integrated circuit, an integrated circuit core, a sensor, a Micro-Electro-Mechanical System (MEMS), a passive device, or a combination thereof.

When a current is applied to the battery Equivalent Circuit Model (ECM), the battery equivalent-model voltage change calculation unit 131 may calculate a voltage change of the battery using parameters related to the State of Charge (SOC). In one embodiment, the battery equivalent-model voltage change calculation unit 131 may calculate the voltage change according to Equation 2.

$${V}_{t , k} - {V}_{t , k - 1} = {R}_{s} ( {I}_{k} - {I}_{k - 1} ) + Δ t / {C}_{1} ( {I}_{k} - {I}_{k - 1} ) + ( 1 - Δ t / {R}_{1} {C}_{1} ) ( {V}_{L , k - 1} - {V}_{L , k - 2} ) \qquad [ Equation 2 ]$$

The voltage change (V_{t,k}−V_{t,k-1}) in Equation 2 represents the difference between the voltage at time k and the voltage at time k−1, and may be used to calculate the voltage change of a battery cell. The inter-cell voltage difference (V_{t,k}−V_{t,k-1}) calculated in Equation 2 may be derived from voltage changes due to internal resistance, voltage changes due to capacitance, and hysteresis effects of the RC circuit.

The voltage change due to internal resistance may be calculated using the term Rₛ (Iₖ−Iₖ₋₁) in Equation 2. In this term, Rₛ represents the resistance of the cell, and (Iₖ−Iₖ₋₁) represents a change in current. This reflects the voltage change caused by the influence of resistance with respect to current change.

The voltage change due to capacitance in the battery equivalent model may be calculated using the term Δt/C₁ (Iₖ−Iₖ₋₁). In this term, C₁ represents the capacity of the capacitor in the battery equivalent model, and Δt represents a time interval. The term representing the voltage change due to capacitance reflects the influence of current change on charging and discharging of the capacitor.

The hysteresis effect of the RC circuit may be calculated by the term (1−×t/R₁C₁)(V_{L,k-1}−V_{L,k-2}). In this term, R₁ and C₁ represent a resistor and a capacitor, respectively, and the term (1−Δt/R₁C₁) represents the characteristics of the RC circuit over time. The term (V_{L,k-1}−V_{L,k-2}) represents the voltage change between two previous points, and this term reflects the influence of the voltage change in a previous cell on the current state.

In one embodiment, when the voltage change due to capacitance Δt/C₁ (Iₖ−Iₖ₋₁) approaches zero (0), it indicates that the voltage change due to the capacitor is negligible. When (1−Δt/R₁C₁) approaches zero, it indicates that the time constant Δt/R₁C₁ is large, meaning that the system response is very fast or the state of the previous point has little influence on the current state.

When the accumulated driving distance exceeds a predetermined value, the driving-distance reflection unit 133 may adjust a ratio of at least one of the calculated values of the voltage change in the battery equivalent model, taking into account degradation differences among cells within the battery module. Thereafter, the adjusted calculated value may be set as a threshold value.

In one embodiment, the driving-distance reflection unit 133 may calculate a voltage deviation variation (DDVD) criterion using Equation 3. The voltage deviation variation (DDVD) criterion may be used to detect a battery abnormality based on voltage deviation variations among the battery cells.

$$( {V}_{max , k} - {V}_{min , k} ) - ( {V}_{max , k - 1} - {V}_{min , k - 1} ) = ( {V}_{t , k} - {V}_{t , k - 1} ) \times a \% \qquad [ Equation 3 ]$$

Referring to Equation 3, the difference between the maximum and minimum voltages at the current point (k) (Vₘₐₓₖ−Vₘᵢₙₖ) represents the voltage difference between the highest and lowest voltage cells in the battery pack. This value represents the voltage deviation at the current point and may be used as an indicator of imbalance among the cells.

The difference between the maximum and minimum voltages at the previous point (k−1), Vₘₐₓₖ₋₁−Vₘᵢₙₖ₋₁, represents the voltage deviation at the previous point. In one embodiment, the voltage deviation at the current point is compared with that at the previous point to evaluate how the voltage deviation has changed.

V_{t,k}−V_{t,k-1} represents the voltage change calculated based on the Equivalent Circuit Model (ECM) and indicates the voltage change between the current point and the previous point estimated from the ECM. This term is used to establish a reference for the actual voltage deviation variation based on the voltage change obtained from the equivalent model. The percentage factor a % adjusts the voltage change by a specific ratio to establish the voltage deviation variation (DDVD) criterion. In one embodiment, the percentage factor a % is preset according to the system design, and the sensitivity to voltage deviation variations may be adjusted.

In one embodiment, the driving-distance reflection unit 133 uses Equation 3 to evaluate the DDVD threshold value through the following process.

First, the driving-distance reflection unit 133 calculates the voltage deviation variation (Vₘₐₓₖ−Vₘᵢₙₖ)−(Vₘₐₓₖ₋₁−Vₘᵢₙₖ₋₁) between the current point and the previous point. This value represents how the imbalance among the cells changes over time. Next, the voltage change of each cell is multiplied by a percentage factor to adjust its contribution to the overall voltage deviation variation. This reflects the influence of a specific cell's voltage change on the voltage deviation variation of the entire battery pack. If the calculated value exceeds a predetermined threshold value, the system may determine that there is an abnormality in the battery cell or pack and issue a warning. In one embodiment, Equation 3 may be used to monitor the voltage imbalance among the battery cells in real time.

In addition, in one embodiment, the driving-distance reflection unit 133 compares the voltage deviation variation criterion calculated using Equation 3 with the driving results of a normal battery, and detects signs of battery abnormality based on the comparison results. For example, the driving-distance reflection unit 133 may determine that the battery is abnormal if the driving result value exceeds the voltage deviation variation criterion, which is adjusted in real time during driving. In one embodiment, the voltage deviation variation criterion repeatedly increases and decreases according to the magnitude of the current. In this case, the voltage deviation variation of a normal battery has a form similar to the threshold value and may be calculated as a ratio value greater than or equal to a predetermined level that does not exceed the criterion.

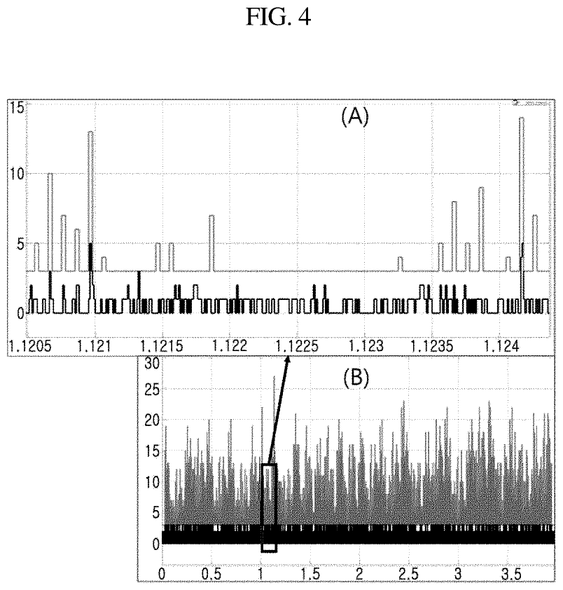

FIG. 4 is a graph showing test results analyzing the voltage deviation of a battery using the voltage deviation variation (DDVD) criterion according to one embodiment of the present disclosure.

FIG. 4(B) is a graph showing the DDVD criterion for voltage changes calculated in the embodiment, and FIG. 4(A) is an enlarged diagram illustrating the change in the DDVD criterion for voltage changes occurring at a specific time.

Referring to FIG. 4(A), the peaks in the upper graph correspond to the voltage changes in the lower graph, indicating that the voltage deviation variation (DDVD) criterion appropriately detects such changes.

Referring again to FIG. 4(A), the green graph at the top visually represents the voltage deviation variation (DDVD) criterion, which serves as a reference value for detecting an abnormality based on the voltage deviation calculated at a specific point in time. Each peak in the graph represents a voltage change occurring over time and indicates the moment when an abnormality is determined according to the voltage deviation variation (DDVD) criterion.

The lower graph shows the voltage deviation variation monitored in the battery. This illustrates how the voltage difference between battery cells changes over time. Voltage variations may occur due to changes in cell states, load, or temperature, and they serve as an important factor in detecting abnormal states.

In one embodiment, the battery abnormality detection device sets the minimum threshold value for voltage abnormality determination to 3 mV. This value is determined in consideration of traditional Diagnostic Trouble Code (DTC) criteria and voltage detection accuracy. In one embodiment, when the voltage deviation variation is 3 mV or more, it may be regarded as an abnormal state. Because the voltage deviation variation criterion includes voltage deviation variations, it reacts sensitively to voltage changes and enables abnormality detection.

The graph of the voltage deviation variation criterion is similar in shape to the voltage deviation variation of the monitored battery. This is because the voltage deviation variation criterion accurately reflects actual voltage change patterns. This indicates that the embodiment can effectively perform abnormality detection corresponding to voltage changes.

FIG. 4 visually demonstrates how effectively the voltage deviation variation (DDVD) criterion responds to actual voltage changes. In addition, it shows how the DDVD criterion detects voltage deviations of 3 mV or more and identifies abnormal states.

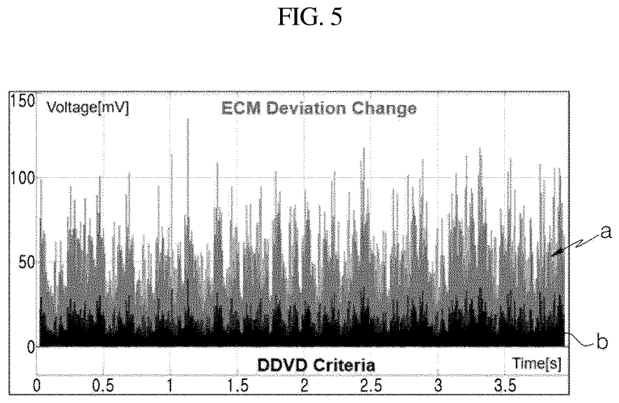

FIG. 5 is a graph illustrating the voltage deviation variation criterion and the deviation change of a monitored Equivalent Circuit Model (ECM) according to one embodiment of the present disclosure.

Referring to FIG. 5, “a” represents the ECM voltage deviation variation, enabling identification of the voltage variability of the ECM over time, and “b” represents the voltage deviation variation criterion. FIG. 5 illustrates the points in time at which abnormalities are detected by comparing the ECM voltage deviation variation. In one embodiment, a voltage change exceeding a predetermined threshold value may be regarded as an abnormal state.

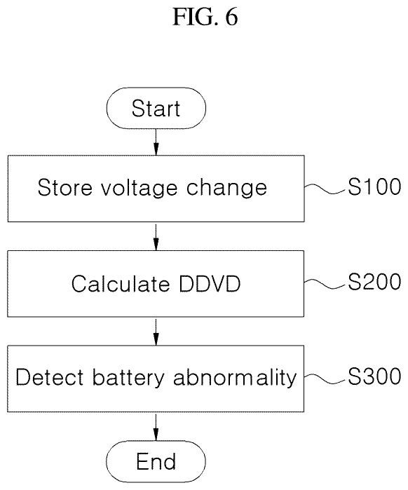

Hereinafter, a battery abnormality detection method of the present disclosure will be described with reference to FIG. 6. The battery abnormality detection method using a voltage deviation variation shown in FIG. 6 may be performed by a battery abnormality detection device 100, which uses a voltage deviation variation and includes the processor 130.

Meanwhile, FIG. 6 is merely illustrative, and the scope of the present disclosure is not limited to those shown therein. For example, the steps may be performed in an order different from that shown in FIG. 6, at least one of the steps shown in FIG. 6 may not be performed, or one or more additional steps not shown in FIG. 6 may be further performed.

Hereinafter, the method for detecting a battery abnormality using a voltage deviation variation will be described in sequence. The operation (function) of the method according to the embodiment is substantially the same as that of the system, and therefore, repetitive descriptions with FIGS. 1 to 5 will be omitted.

FIG. 6 is a flowchart illustrating the method for detecting a battery abnormality using a voltage deviation variation according to one embodiment of the present disclosure.

Referring to FIG. 6, in step S100, the voltage change of the battery is calculated, and the calculated voltage change is stored as a variable. In step S200, the voltage deviation variation (DDVD), which is a change in voltage difference among respective cells within a battery module, is calculated. In step S300, a battery abnormality is detected using the voltage deviation variation (DDVD) and the stored variable.

According to the problem-solving means of the present disclosure described above, the effect of enabling adaptation to various operating conditions and changes in the battery state may be provided by dynamically adjusting the threshold value for determining battery abnormality based on the current change.

Furthermore, according to the problem-solving means of the present disclosure described above, abnormality detection errors may be reduced by setting the voltage change, which serves as the criterion for abnormality determination, as a variable using a battery equivalent model instead of a constant, thereby reflecting current usage patterns.

In addition, according to the problem-solving means of the present disclosure described above, by managing the battery based on the voltage deviation variation instead of the voltage change, abnormality detection errors due to parameter errors in the battery equivalent model may be further reduced.

Furthermore, according to the problem-solving means of the present disclosure described above, the normal battery state may be effectively determined under various states, such as fast charging or high-power discharging.

Furthermore, according to the problem-solving means of the present disclosure described above, by using a variable threshold value instead of a fixed threshold value, false positives and false negatives may be reduced, thereby enabling more accurate detection of actual abnormal signs of the battery.

In addition, according to the problem-solving means of the present disclosure described above, by using a battery equivalent model that reflects the physical and chemical characteristics of the battery, it is possible to more precisely predict changes in voltage, internal resistance, and other variables associated with current variation. This provides a deeper understanding than simple voltage change detection and enables a more detailed assessment of the battery state.

Furthermore, according to the problem-solving means of the present disclosure described above, abnormality detection based on the equivalent model enables proactive prediction and response to problems before the battery reaches a critical state. This may contribute to extended cycle life and stable operation of the battery.

Furthermore, according to the problem-solving means of the present disclosure described above, since the parameters of the battery equivalent model may vary depending on battery degradation or ambient temperature changes, the effect of reducing errors in the calculated threshold value can be achieved by taking these variations into account.

In addition, according to the problem-solving means of the present disclosure described above, by monitoring deviations among multiple cells within the battery module and managing relative changes, it is possible to minimize the influence of individual cell parameter variations on overall abnormality detection.

Furthermore, according to the problem-solving means of the present disclosure described above, by detecting abnormalities based on relative changes among cells instead of absolute values, the influence of parameter errors may be reduced, thereby enabling more stable abnormality detection.

Furthermore, according to the problem-solving means of the present disclosure described above, by reflecting battery characteristics that vary depending on environmental conditions (such as temperature and humidity), it is possible to maintain high reliability even under various environmental conditions. This ensures that battery reliability can be maintained even in electric vehicles, drones, and outdoor devices that are subject to significant environmental variations.

In addition, according to the problem-solving means of the present disclosure described above, by performing current change-based detection, abnormal signs can be detected at an early stage before incidents such as fire occur, thereby allowing for timely and appropriate response measures. Furthermore, according to the problem-solving means of the present disclosure described above, by accurately identifying the battery state and detecting abnormal signs in advance, unnecessary maintenance costs may be reduced. This contributes to a reduction in overall operational costs and enables the efficient use of resources.

The disclosed subject matter is merely illustrative, and various modifications and implementations may be made by those skilled in the art without departing from the spirit and scope of the claims. Accordingly, the scope of protection of the present disclosure is not limited to the specific embodiments described above.

What is claimed is:

1. A device for detecting a battery abnormality using a voltage deviation variation, the device comprising:
a memory configured to store at least one instruction for detecting a battery abnormality using a voltage deviation variation; and
a processor configured to perform an operation according to the instruction,
wherein the processor is configured to:
calculate a voltage change of the battery and store the calculated voltage change as a variable; and
calculate a Differential Deviation Voltage Detection (DDVD), which is a change in voltage difference among respective cells within a battery module, and detect a battery abnormality using the Differential Deviation Voltage Detection (DDVD) and the stored variable.

2. The device according to claim 1, wherein the processor comprises a battery equivalent-model voltage change calculation unit configured to calculate a voltage change of the battery using parameters related to a State of Charge (SOC) of the battery when a current is applied to an Equivalent Circuit Model (ECM).

3. The device according to claim 2, wherein the processor comprises a driving-distance reflection unit configured to, when an accumulated driving distance exceeds a predetermined value,
adjust a ratio of at least one of the calculated values of the voltage change in the battery equivalent model by taking into account degradation differences among cells within the battery module, and
set the adjusted calculated value as a voltage deviation variation (DDVD) criterion.

4. The device according to claim 2, wherein the parameters related to the State of Charge (SOC) include a voltage change (Δt/C₁ (Iₖ−Iₖ₋₁) due to capacitance of the battery equivalent model and circuit characteristics (1−Δt/R₁C₁) of an RC circuit.

5. The device according to claim 3, wherein the driving-distance reflection unit is configured to compare the calculated voltage deviation variation criterion with driving results of a normal battery, and adjust an increase or decrease of the criterion according to a current level.

6. A method for detecting a battery abnormality using a voltage deviation variation, the method comprising:
calculating a voltage change of the battery and storing the calculated voltage change as a variable; and
calculating a Differential Deviation Voltage Detection (DDVD), which is a change in voltage difference among respective cells within a battery module, and detecting a battery abnormality using the Differential Deviation Voltage Detection (DDVD) and the stored variable.

7. The method according to claim 6, wherein the step of detecting a battery abnormality comprises calculating, by a battery equivalent-model voltage change calculation unit, a voltage change of the battery using parameters related to a State of Charge (SOC) of the battery when a current is applied to an Equivalent Circuit Model (ECM).

8. The method according to claim 7, wherein the step of calculating a voltage change of the battery comprises:
when an accumulated driving distance exceeds a predetermined value, by a driving-distance reflection unit, adjusting a ratio of at least one of the calculated values of the voltage change in the battery equivalent model by taking into account degradation differences among cells within the battery module; and setting the adjusted calculated value as a voltage deviation variation (DDVD) criterion.

9. The method according to claim 7, wherein the parameters related to the State of Charge (SOC) include a voltage change (Δt/C₁ (Iₖ−Iₖ₋₁) due to capacitance of the battery equivalent model and circuit characteristics (1−Δt/R₁C₁) of an RC circuit.

10. The method according to claim 8, wherein the step of setting the adjusted calculated value as a voltage deviation variation (DDVD) criterion comprises:
comparing the calculated voltage deviation variation criterion with driving results of a normal battery, and adjusting an increase or decrease of the criterion according to a current level.
